(19) United States
(12) Patent Application Publication
(10) Pub. No.: US 2011/0134686 A1
(43) Pub. Date: Jun. 9, 2011

(54) SEMICONDUCTOR DEVICES INCLUDING SENSE AMPLIFIER CONNECTED TO WORD LINE

(75) Inventors: Han Gu Sohn, Suwon-si (KR); Dong Yang Lee, Yongin-si (KR)

(73) Assignee: SAMSUNG ELECTRONICS CO., LTD., Suwon-si (KR)

(21) Appl. No.: 12/955,952

(22) Filed: Nov. 30, 2010

(30) Foreign Application Priority Data
Dec. 7, 2009 (KR) 10-2009-0120457

(51) Int. Cl. G11C 7/06; G11C 11/21; G06F 12/00

(52) U.S. Cl. 365/163; 365/189.011; 365/189.15; 365/189.16; 711/102; 711/E12.007

(57) ABSTRACT

A semiconductor device includes a plurality of non-volatile memory cells connected between a plurality of word lines and a plurality of bit lines, respectively, and a sense amplifier block for sensing and amplifying a signal of a word line among the plurality of word lines.

### CROSS-REFERENCE TO RELATED APPLICATIONS

A claim of priority under 35 U.S.C. §119 is made to Korean Patent Application No. 10-2009-0120457, filed on Dec. 7, 2009, the disclosure of which is hereby incorporated by reference in its entirety.

### BACKGROUND

Embodiments of the inventive concepts described herein generally relate to semiconductor devices, and more particularly, to semiconductor devices including a sense amplifier connected to a word line.

Each memory cell of a phase-change memory (PRAM) device generally includes a phase-change element and a selection element for selectively connecting the phase-change element to word and bit lines. A diode, for example, may be utilized for the selection element in order to reduce a size of the memory cell. The phase-change element includes a phase change material having variable resistance characteristics, such as, for example, Ge₂Sb₂Te₅ (GST). The phase-change material is responsive to programming currents to be stably programmed in at least a low-resistance crystal state or a high-resistance amorphous state. The resistive states are assigned bit values which can be discerned by application of a read current (or voltage) to the memory cell in a read operation.

### SUMMARY

The present inventive concepts generally provide semiconductor devices including a sense amplifier connected to a word line.

According to an aspect of the inventive concepts, a semiconductor device is provided which includes a word line and a bit line connected to a non-volatile memory cell, and a sense amplifier for sensing and amplifying a signal of the word line during a read operation.

According to another aspect of the inventive concepts, a semiconductor device is provided which includes a plurality of non-volatile memory cells connected between a plurality of word lines and a plurality of bit lines, respectively, and a sense amplifier block for sensing and amplifying a signal of a first word line among the plurality of word lines.

According to yet another aspect of the inventive concepts, a semiconductor system is provided which include a semiconductor device and a processor controlling an operation of the semiconductor device, where the semiconductor device includes a word line and a bit line connected to a non-volatile memory cell, and a sense amplifier for sensing and amplifying a signal of the word line during a read operation.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 shows a block diagram of a semiconductor device according to an example embodiment of the present invention;

FIG. 2 shows a part of the semiconductor device illustrated in FIG. 1, which includes a sense amplifier block according to an example embodiment of the present invention;

FIG. 3 shows a part of the semiconductor device of FIG. 1, which includes a sense amplifier block according to another example embodiment of the present invention; and

FIG. 4 shows a block diagram of a semiconductor system including the semiconductor device illustrated in FIG. 1.

### DETAILED DESCRIPTION OF EMBODIMENTS

Reference will now be made in detail to embodiments of the inventive concepts, examples of which are illustrated in the accompanying drawings, wherein like reference numerals refer to the like elements throughout. The embodiments are as examples of the inventive concepts, and are not intended to limit the scope of the inventive concepts.

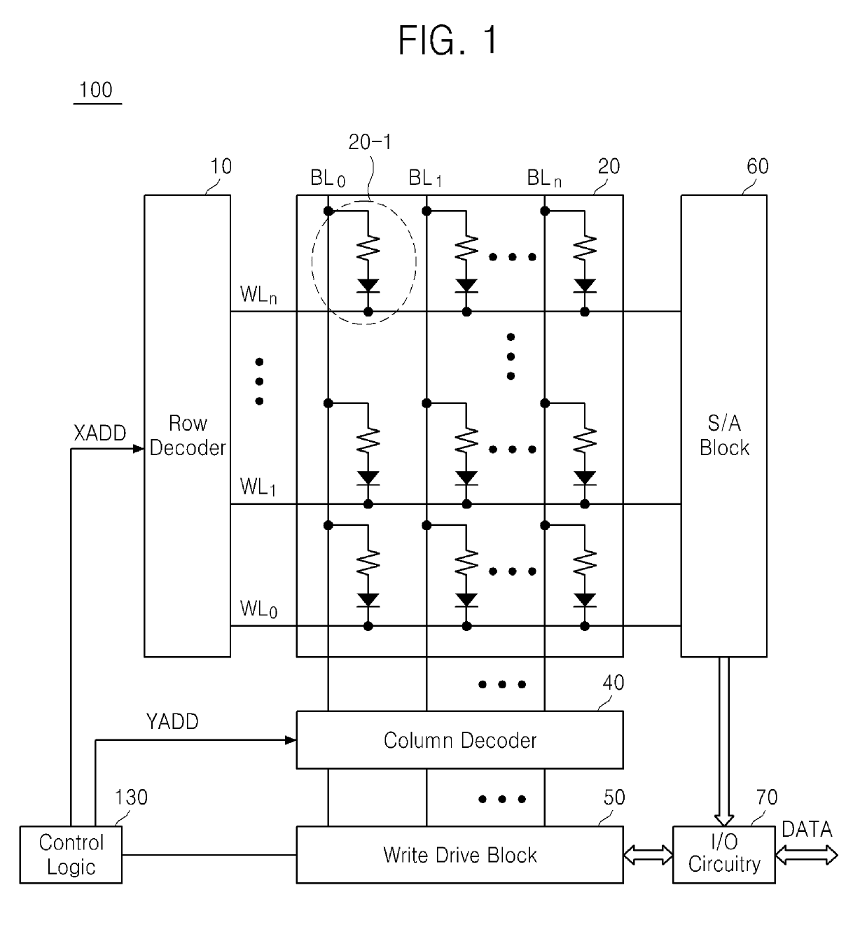

FIG. 1 shows a block diagram of a semiconductor device according to an example embodiment of the inventive concepts. Referring to FIG. 1, the semiconductor device 100 of this example includes a row decoder 10, a memory cell array 20, a column decoder 40, a write driver block 50, a sense amplifier block 60, an input/output circuit 70 and a control logic 130.

The memory cell array 20 includes the plurality of word lines WL₀ to WLₙ, a plurality of bit lines BL₀ to BLₙ and a plurality of non-volatile memory cells 20-1 connected between the plurality of word lines WL₀ to WLₙ and the plurality of bit lines BL₀ to BLₙ, respectively.

Each of the plurality of non-volatile memory cells 20-1 may, for example, be a phase change memory cell. Each phase change memory cell 20-1 includes a phase change element for storing data based on a resistive state thereof, and a selection element for selectively connecting the phase change element between a corresponding bit line BL and word line WL. In the example of FIG. 1, the selection element is a diode connected in series with the phase change element between a bit line BL and word line WL. The phase change material of the phase change element may, for example, be a chalcogenide alloy such as Ge₂Sb₂Te₅ (GST). Generally, a phase change memory cell is programmed to one of at least two resistive states, e.g., a high resistance amorphous state (called a RESET state) or a low resistance crystalline state (called a SET state). Programming is carried by selective Joule heating of the phase change material by application of a current or voltage to the phase change memory cell.

Still referring to FIG. 1, the row decoder 10 selects one of the plurality of word lines WL₀ to WLₙ, embodied in the memory cell array 20, by decoding row address signals XADD output from the control logic 130.

The column decoder 40 selects at least one of the plurality of bit lines BL₀ to BLₙ, embodied in the memory cell array 20, by decoding column address signals YADD output from the control logic 130. Accordingly, at least one of the plurality of non-volatile memory cells 20-1 embodied in the memory cell array 20 is selected by joint operation of the row decoder 10 and the column decoder 40 during a write operation or a read operation.

The write driver block 50 includes a plurality of write drivers. Each of the plurality of write drivers applies a write current (or voltage) to corresponding a bit line BL selected by the column decoder 40 according write data output from an input/output circuit 70 during a write operation.

The sense amplifier block 60 includes a plurality of sense amplifiers. Each of the plurality of sense amplifiers determines if data stored in a corresponding memory cell is data ‘0’ or data ‘1’ by sensing and amplifying a signal of a word line, e.g., a current signal or a voltage signal, selected by the row decoder 10. The read data sensed and amplified by the sense amplifier block 60 may be transmitted to an external device through the input/output circuit 70 during a read operation.

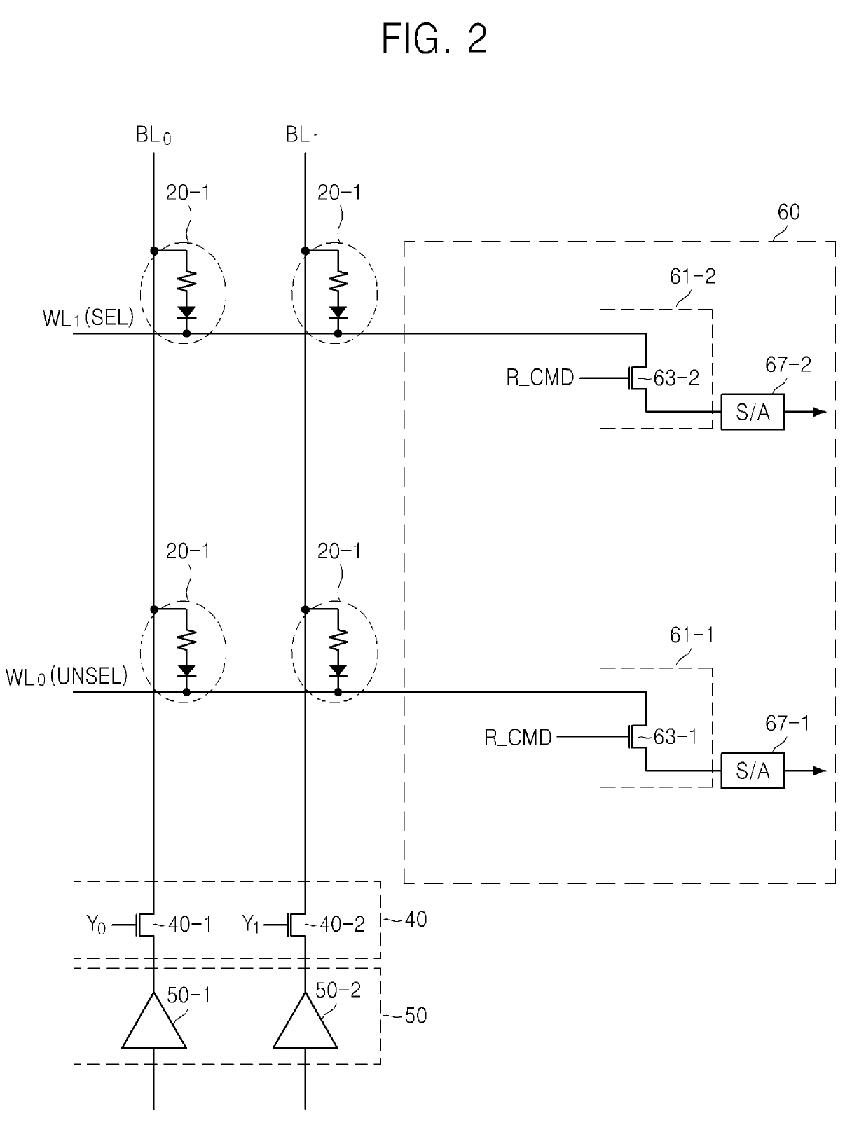

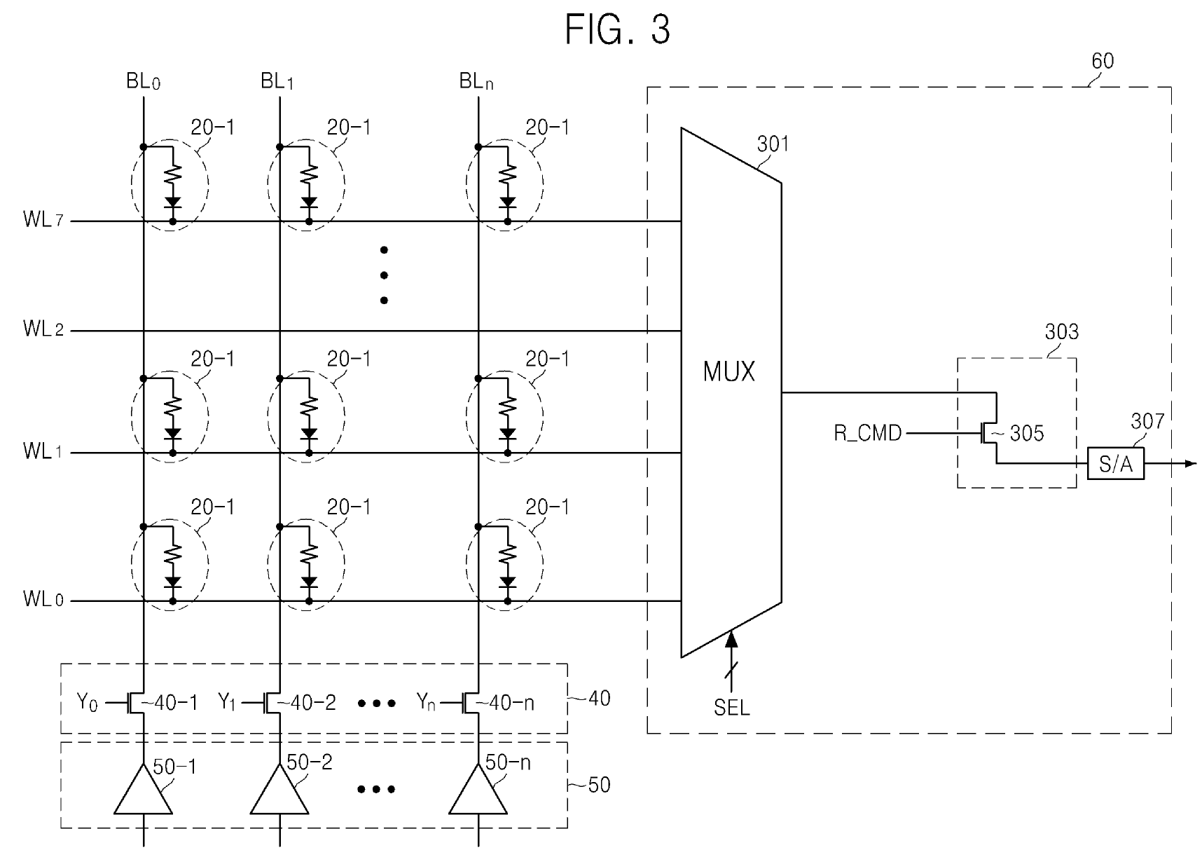

In addition to controlling generation of the address row addresses XADD and column addresses YADD, the control logic 130 controls an operation of the write driver block 50 and/or an operation of the sense amplifier block 60 in response to command signals input from an external source. According to embodiments, the control logic 130 may, in response to a read command during a read operation, generate a signal related to the read command, e.g., a switching control signal R_CMD (described later and shown in FIGS. 2-3).

The input/output circuit 70 of this example transmits write data input from an external source to the write driver block 50 during a write operation, and transmits read data sensed and amplified by the sense amplifier block 60 to an external source during a read operation.

The semiconductor device 100 of FIG. 1 includes the write driver block 50 which is responsive to write data to drive at least a bit line selected from among a plurality of bit lines BL₀ to BLₙ, and the sense amplifier block 60 for sensing and amplifying a signal of at least one word line selected from among a plurality of word lines WL₀ to WLₙ during a read operation. In other words, write currents (or voltages) are applied to the bit lines BL, and read currents (or voltages) are sensed from the word lines WL. The write driver block 50 and the sense amplifier block 60 may be embodied as separate circuit blocks as in FIG. 1, or combined into a single circuit block.

FIG. 2 shows a portion of the semiconductor device of FIG. 1, which includes a sense amplifier block according to an example embodiment of the inventive concepts. To simplify the explanation, FIG. 2 illustrates only two bit lines BL₀ and BL₁, two word lines WL₀ and WL₁, four non-volatile memory cells 20-1, and corresponding portions of column select, write driver and sense circuits 40, 50 and 60.

Referring to FIGS. 1 and 2, the sense amplifier block 60 includes sense selection switches 61-1 and 61-2 and sense amplifiers 67-1 and 67-2 allocated to respective word lines WL0 and WL1.

The column decoder 40 includes column selection switches 40-1 and 40-2 allocated to respective bit lines B10 and BL1, and the write driver block 50 includes write drivers 50-1 and 50-2 allocated to the respective bit lines BL0 and BL1.

During a write operation, assuming that a second word line WL₁ is selected by the row decoder 10 and a first bit line BL₀ is selected by the column decoder 40, a first write driver 50-1 may write data in a non-volatile memory cell 20-1 connected to the second word line WL₁ and the first bit line BL₀. For example, a GST material may be programmed to a crystal SET state or an amorphous RESET state in response to a current or a voltage supplied to the first bit line BL₀. In this case, the first selection switch 40-1 is turned on in response to a first selection signal Y0 having a high level, and the second selection switch 40-2 retains its off state in response to a second selection signal Y1 having a low level. The selection signals Y0 and Y1 are signals corresponding to column address signals.

In addition, for example, a voltage, e.g., 2.5V to 3V, supplied to the unselected first word line WL₀ during a write operation may be higher than a voltage (for example, 0V) supplied to the selected second word line WL₁. Further, a voltage, e.g., 2V to 2.5V, supplied to a first bit line BL₀ may be lower than a voltage, e.g., 2.5V to 3V, supplied to the first word line WL₀, and may be higher than a voltage, e.g., 0V, supplied to the second word line WL₁.

During a write operation, a level of a signal R_CMD related to a read command is a first level, e.g., a low level. Subsequently, each transmission circuit 61-1 and 61-2 becomes disabled. Here, the signal R_CMD may be a read command itself or a signal generated in response to the read command. The read command may also be a signal determined according to combination of a plurality of signals.

For an ease of explanation, FIG. 2 illustrates each transmission circuit 61-1 and 61-2 being implemented with an NMOS transistor, which may be turned on in response to a signal R_CMD related to a read command which is a high logic signal. However, each transmission circuit 61-1 and 61-2 may be embodied in a PMOS transistor which may be turned on in response to a signal R_CMD related to a read command which is a low logic signal. According to another example embodiment, each transmission circuit 61-1 and 61-2 may be embodied in a transmission gate performing a transmission operation in response to the signal R_CMD related to a read command.

The read operation may be explained referring to FIGS. 1 and 2 as follows. During a read operation, a level of a signal R_CMD associated with a read command is a second level, e.g., a high level, and thus each transmission circuit 61-1 and 61-2 becomes enabled. In addition, each non-volatile memory cell 20-1 becomes effectively turned-on or turned-off based on a signal level of each word line WL₀ to WL₁.

When a second word line WL₁ is selected by the row decoder 10 and a first bit line BL₀ is selected by the column decoder 40, a signal of the second word line WL₁ is supplied to a second sense amplifier 67-2 through the second transmission circuit 61-2 (enabled by the high-level signal R_CMD). The sense amplifier 67-2 may therefore determine whether data ‘0’ or ‘1’ is stored in a non-volatile memory cell connected between the second word line WL₁ and the first bit line BL₀ based on the signal input through the second transmission circuit 61-2.

During a read operation, a voltage, e.g., 1.3V, supplied to an unselected first word line WL0 may be higher than a voltage, e.g., 0V, supplied to a selected second word line WL1. Here, a voltage, e.g., 2V to 2.5V, supplied to a first bit line BL0 is higher than a voltage, e.g., 1.3V, supplied to the first word line WL0 and higher than a voltage, e.g., 0V, supplied to the second word line WL1. According to embodiments, each sense amplifier 67-1 and 67-2 may be a sense amplifier sensing and amplifying a current or a voltage.

FIG. 3 shows a part of the semiconductor device of FIG. 1, which includes a sense amplifier block according to another example embodiment of the present invention. Referring to FIG. 3, a sense amplifier 307 may sense and amplify a signal output from each of a plurality of word lines WL0 to WL7. Accordingly, a sense amplifier block 60 includes a selector 301 for outputting one of the plurality of word lines WL0 to WL7 selectively in response to a selection signal (or digital bits) SEL.

During a write operation, each of a plurality of selection switches 40-1 to 40-n embodied in the column decoder 40 may transmit a write data output from each of a plurality of drivers 50-1 to 50-n to each of a plurality of bit lines BL₀ to BLₙ in response to each of a plurality of selection signals Y0 to Yn. During a read operation, it is assumed that each of the plurality of word lines WL0 to WL7 connected to a first bit line BL0 is selected successively by the row decoder 10, a signal R_CMD related to a read command having a second level is supplied to a transmission circuit 303, and the selection signal SEL is increased successively by 1 from 000 to 111.

The transmission circuit 303 becomes enabled in response to the signal R_CMD related to the read command having the second level.

The selector 301 transmits a signal of a first word line WL₁ to the sense amplifier 307 in response to a selection signal SEL, e.g., 000. Accordingly, the sense amplifier 307 may determine if data stored in a non-volatile memory cell connected between the first word line WL₁ and a first bit line BL₀ is “0” or “1” based on a signal of the first word line WL₁. Additionally, the selector 301 transmits a signal of a second word line WL2 to the sense amplifier 307 in response to a selection signal SEL, e.g., 001. Accordingly, the sense amplifier 307 may determine if data stored in a non-volatile memory cell connected between the second word line WL₂ and the first bit line BL₀ is “0” or “1” based on a signal of the second word line WL₂.

In the same way as described above, the selector 301 transmits a signal of each word line WL3 to WL7 successively to the sense amplifier 307 in response to the selection signal SEL increasing successively by 1 from 010 to 111. Accordingly, the sense amplifier 307 may determine if data stored in a corresponding non-volatile memory cell is “0” or “1” based on a signal of each word line WL3 to WL7. According to embodiments, a selection signal (or digital bits) SEL is generated by the control logic 130.

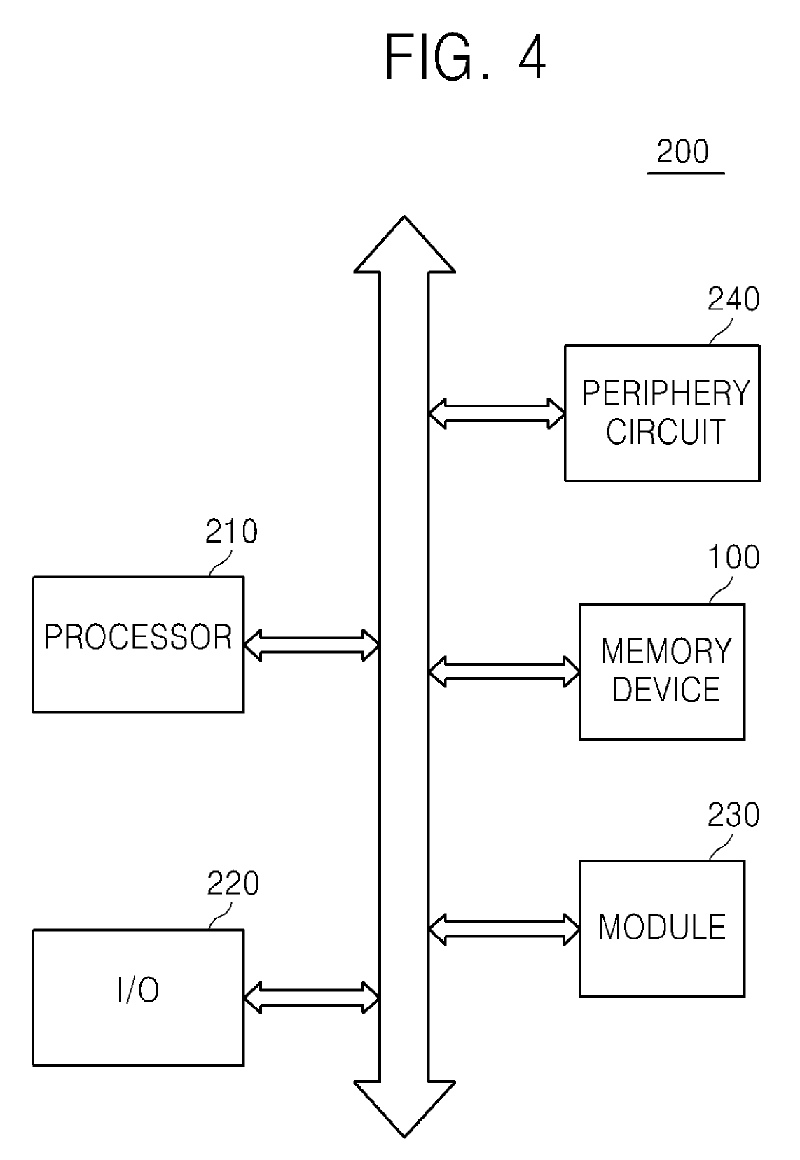

FIG. 4 shows a block diagram of a semiconductor system including the semiconductor device illustrated in FIG. 1. The semiconductor system 200 may be embodied as a personal computer (PC), a tablet PC, a lap-top computer, a net-book, a cellular phone, a smart phone, a personal digital assistant (PDA), a portable multimedia player (PMP), a MP3 player, an e-book, a memory card, a smart card, a home automation device or a consumer equipment (CE).

Referring to FIG. 4, the semiconductor system 200 includes the memory device 100 and a processor 210. An operation of the semiconductor system is explained referring to FIGS. 1 to 4 as follows.

During a write operation, the memory device 100 includes the sense amplifier block 60 illustrated in FIG. 2 or 3, and may write a write data output from a processor 210 in the memory cell array 20 by using the write driver block 50. In addition, during a read operation, the memory device 100 may sense and amplify a signal of at least one of a plurality of word lines WL₁ to WLₙ, which are embodied in the memory cell array 20, by using the sense amplifier block 60 in response to a command and address signals output from the processor 210. A read data output from the sense amplifier block 60 may be transmitted to the processor 210 through the input/output circuit 70 and a bus. That is, the processor 210 may control a write operation or a read operation of the memory device 100.

The semiconductor system 200 may further include an input/output device 220. The input/output device 220 may be embodied as a keyboard, a mouse or a touch panel. The input/output device 220 may be also a display device or a speaker.

The semiconductor system 200 may further include a module 230. When the module is embodied as an image sensor, the semiconductor system 200 may be an image processing device, e.g., a digital camera, a cellular phone with a digital camera installed in, a scanner or a CCTV system.

In this case, an image signal output from the image sensor may be written in at least one of a plurality of non-volatile memory cells through a write driver block 50 of the memory device 100 and at least one of a plurality of bit lines under a control of the processor 210.

Moreover, data stored in at least one of the plurality of non-volatile memory cells embodied in the memory device 100 may be transmitted to the sense amplifier block 60 through at least one of a plurality of word lines. Accordingly, the sense amplifier block 60 may determine if data stored in a corresponding non-volatile memory cell is data ‘0’ or data ‘1’ by sensing and amplifying a signal, e.g., a voltage or a current, of at least one of the plurality of word lines.

When the module 230 is embodied as a wireless communication module for a radio communication, the semiconductor system 200 may be a wireless communication system, e.g., a cellular phone or a RFID system. The wireless communication module may exchange data with the memory device 100 under a control of the processor 210. The semiconductor system 200 may further include a peripheral circuit 240. The peripheral circuit 240 may be a USB port or a serial port.

The semiconductor device according to embodiments of the present invention may, by sensing and amplifying a signal of a word line, determine data stored in a non-volatile memory cell connected to the word line.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor device comprising:
a word line and a bit line connected to a non-volatile memory cell; and
a sense amplifier for sensing and amplifying a signal of the word line during a read operation.

2. The semiconductor device of claim 1, wherein the non-volatile memory cell is a phase change memory.

3. The semiconductor device of claim 2, wherein the phase change memory cell includes a phase change element and a diode connected in series between the bit line and the word line.

4. The semiconductor device of claim 1, further comprising a transmission circuit for transmitting the signal of the word line to the sense amplifier in response to a signal in accordance with a read command

5. The semiconductor device of claim 1, further comprising a write driver for driving the bit line according to write data, wherein the write driver and the sense amplifier are separated from each other.

6. The semiconductor device of claim 5, further comprising a row decoder for selecting the word line according to an address signal, wherein the row decoder and the sense amplifier are connected to opposite sides of the word line.

7. A semiconductor device comprising:
a plurality of non-volatile memory cells connected between a plurality of word lines and a plurality of bit lines, respectively; and
a sense amplifier block for sensing and amplifying a signal of a first word line among the plurality of word lines.

8. The semiconductor device of claim 7, wherein each of the plurality of non-volatile memory cells is a phase change memory.

9. The semiconductor device of claim 8, wherein each phase change memory cell includes a phase change element and a diode connected in series between a corresponding bit line and word line.

10. The semiconductor device of claim 7, wherein the sense amplifier block comprises:
a selector for outputting the signal of the first word line among the plurality of word lines in response to a selection signal; and
a transmission circuit for transmitting an output signal of the selector to the sense amplifier in response to a switching control signal.

11. The semiconductor device of claim 10, wherein the switching control signal is in accordance with a read command.

12. The semiconductor device of claim 10, further comprising a row decoder for selecting a word line among the plurality of word lines according to an address signal, wherein the row decoder and the selector are connected to opposite sides of the word lines.

13. The semiconductor device of claim 7, further comprising a row decoder for selecting a word line among the plurality of word lines according to an address signal, wherein the row decoder and the sense amplifier block are connected to opposite sides of the word lines.

14. A semiconductor system comprising a semiconductor device and a processor controlling an operation of the semiconductor device, wherein the semiconductor device comprises:
a word line and a bit line connected to a non-volatile memory cell; and
a sense amplifier for sensing and amplifying a signal of the word line during a read operation.

15. The semiconductor system of claim 14, wherein the non-volatile memory cell is a phase change memory.

16. The semiconductor device of claim 15, wherein the phase change memory cell includes a phase change element and a diode connected in series between the bit line and the word line.

17. The semiconductor system of claim 14, wherein the semiconductor device further comprises a transmission circuit for transmitting the signal of the word line to the sense amplifier in response to a signal in accordance with a read command.

18. The semiconductor system of claim 14, wherein the semiconductor device further comprises a write driver for driving the bit line according to write data, and wherein the sense amplifier and the write driver are separated from each other.

19. The semiconductor system of claim 14, wherein the word line, the bit line and the non-volatile memory cell are a first word line, a first bit line and a first non-volatile memory cell, respectively, and where the semiconductor device further comprises:
a second word line and a second bit line connected to a second non-volatile memory cell; and
a selector for transmitting the signal of the first word line or a signal of the second word line to the sense amplifier in response to a selection signal.

20. The semiconductor system of claim 17, wherein the word line, the bit line and the non-volatile memory cell are a first word line, a first bit line and a first non-volatile memory cell, respectively, and where the semiconductor device further comprises:
a second word line and a second bit line connected to a second non-volatile memory cell; and
a selector for transmitting the signal of the first word line or a signal of the second word line to the transmission circuit in response to a selection signal.
